(19) United States
(12) Patent Application Publication
(10) Pub. No.: US 2007/0271052 A1
(43) Pub. Date: Nov. 22, 2007

(54) Method and apparatus for measuring duty cycle based on data eye monitor

(76) Inventors: Christopher J. Abel, Coplay, PA (US); Mohammad S. Mobin, Orefield, PA (US); Gregory W. Sheets, Bangor, PA (US); Lane A. Smith, Easton, PA (US)

Correspondence Address: RYAN, MASON & LEWIS, LLP, 1300 POST ROAD, SUITE 205, FAIRFIELD, CT, 06824, US

(21) Appl. No.: 11/434,686

(22) Filed: May 16, 2006

(51) Int. Cl. G01R 25/00; G01R 29/02

(52) U.S. Cl. 702/79

(57) ABSTRACT

Methods and apparatus are provided for measuring the duty cycle of a signal based on a data eye monitor. The duty cycle of a signal is estimated by sampling the signal for a plurality of different phases and evaluating the samples to identify when the signal crosses a predefined amplitude value. The duty cycle is estimated based on a statistical variation between the points of predefined amplitude crossing, such as points of zero crossing. The duty cycle can optionally be corrected based on the measured duty cycle value. The sampling of the signal may be performed, for example, using one or more latches.

### CROSS REFERENCE TO RELATED APPLICATIONS

The present application is related to U.S. patent application Ser. No. ______, entitled “Methods and Apparatus for Evaluating the Eye Margin of a Communications Device Using a Data Eye Monitor,” and U.S. patent application Ser. No. ______, entitled “Method and Apparatus for Determining One or More Channel Compensation Parameters Based on Data Eye Monitoring,” each filed contemporaneously herewith and incorporated by reference herein.

### FIELD OF THE INVENTION

The present invention is related to techniques for duty cycle correction and, more particularly, to techniques for measuring duty cycle of a signal based on a data eye monitor.

### BACKGROUND OF THE INVENTION

In many applications, including digital communications, Phase-Locked Loop (PLL) clock circuits or Delay-Locked Loop (DLL) clock circuits are employed to generate one or more clock signals. A PLL compares two clock signals, such as input and output clock signals, and generates an output clock signal that is aligned with the input clock signal. Generally, two clock signals are aligned when an edge of the output clock signal occurs at approximately the same time (e.g., within some error threshold) as an edge of the input clock signal. Generally, rising edges are used so that a rising edge of the output clock signal occurs at about the same time as a rising edge of the input clock signal. Typically, a PLL comprises a phase comparator, low pass filter, and Voltage Controlled Oscillator (VCO). The phase comparator compares the input and output clock signals and produces an output signal that is related to the phase offset between the input and output clock signals. The filter smooths the output of the phase comparator, and the VCO oscillates at a rate proportional to the voltage applied to the VCO from an output of the filter.

PLLs are used in a wide variety of situations, such as clock recovery from encoded digital streams, synchronization of clock signals, synchronization of input and output data, and locking onto a signal such as a radio signal. While PLLs are widely used, some problems with PLLs exist. For instance, conventional PLLs typically exhibit some duty cycle distortion. The duty cycle of a PLL is the percentage of time that the output clock signal has a given value. A PLL should typically demonstrate a 50% duty cycle, such that the output clock signal should alternate between two amplitude values, each for 50% of the total duration. Duty cycle mismatches arise due to mismatches in the devices and due to variations of the differential signal paths for clock and data. The target 50% duty cycle feature is particularly important for high-speed applications where both positive and negative edges are used.

A need therefore exists for a duty cycle correction mechanism that can implement such high-speed duty cycle measurements. A further need exists for techniques for measuring duty cycle based on data eye monitoring.

### SUMMARY OF THE INVENTION

Generally, methods and apparatus are provided for measuring the duty cycle of a signal using a data eye monitor. According to one aspect of the invention, the duty cycle of a signal is estimated by sampling the signal for a plurality of different phases and evaluating the samples to identify when the signal crosses a predefined amplitude value. The duty cycle is estimated based on the statistical variation between the points of predefined amplitude crossing, such as points of zero crossing (i.e., symbol-by-symbol variation in zero crossing times, as represented by the width of the zero crossing transitions). The duty cycle can optionally be corrected based on the measured duty cycle value.

The sampling of the signal may be performed, for example, using one or more latches. In one implementation, a first fixed latch is fixed approximately in a center of a data eye associated with the signal and a second roaming latch can be repositioned to sample various portions of the signal. The values of the fixed and roaming latches can be compared to identify when the signal crosses the predefined amplitude value.

When the signal being evaluated is a clock signal, the statistical variation between the points of predefined amplitude crossing can be obtained by determining a number of occurrences of a first amplitude value, such as a value of binary one, or a number of occurrences of a second amplitude value, such as a value of binary zero, for each unit interval. The number of ones and zeros can be compared to estimate the duty cycle. A 50% duty cycle, for example, should exhibit an equal number of ones and zeros for each alternating unit interval.

When the signal being evaluated contains random data, the statistical variation between the points of predefined amplitude crossing can be obtained by generating a histogram based on the sampled values. In an exemplary implementation, the points of predefined amplitude crossing, such as points of zero crossing, will exhibit peaks in the histogram. The duty cycle can thus be estimated based on a statistical variation between the peaks in the histogram. A more complete understanding of the present invention, as well as further features and advantages of the present invention, will be obtained by reference to the following detailed description and drawings.

### BRIEF DESCRIPTION OF THE DRAWINGS

FIG. 1 illustrates a measured unit interval of a signal;

FIG. 2 illustrates an exemplary signal flow for a duty cycle monitoring operation in accordance with the present invention;

FIG. 3 is a schematic block diagram of a first embodiment of a duty cycle monitor incorporating features of the present invention;

FIG. 4 is a schematic block diagram of a second embodiment of a duty cycle monitor incorporating features of the present invention;

FIG. 5 illustrates the measurement of the unit interval of a data eye and duty cycle distortion in accordance with one embodiment of the present invention;

FIG. 6 illustrates one embodiment of the roaming latches of FIGS. 3 and 4;

FIG. 7 is a circuit diagram illustrating an exemplary implementation of the duty cycle correction circuit of FIG. 2;

FIG. 8 is a schematic block diagram illustrating a control system for meausing duty cycle based on the data eye; and

FIG. 9 is a flow chart describing an exemplary duty cycle monitoring process incorporating features of the present invention.

### DETAILED DESCRIPTION

The present invention provides methods and apparatus for duty cycle monitoring. The disclosed duty cycle monitoring techniques digitally measure the duty cycle variation and correct the duty cycle error using digital control techniques (such as hardware or microprocessor based duty cycle correction). According to one exemplary embodiment of the invention, the unit interval (UI) for each eye is measured using a data eye monitor and the unit interval measurement provides an indication of the duty cycle. The exemplary data eye monitor may be implemented, for example, using the techniques described in U.S. patent application Ser. No. 11/095,178, filed Mar. 31, 2005, entitled “Method and Apparatus for Monitoring a Data Eye in a Clock and Data Recovery System,” incorporated by reference herein. Generally, one or more latches associated with the exemplary data eye monitor are used to determine the unit interval of each eye in the signal.

FIG. 1 graphically illustrates a measured unit interval of a signal 100. It is noted that the signal 100 is shown as a series of data eyes 110-1 through 110-N. Each data eye 110 is a superposition of a number of individual signals, in a known manner. As discussed further below, the signal 100 is sampled by one or more roaming latches to determine whether the measured unit interval for each eye 110 is approximately the same. For example, the first data eye 110-1 has a corresponding unit interval 150-1 and the second data eye 110-2 has a corresponding unit interval 150-2.

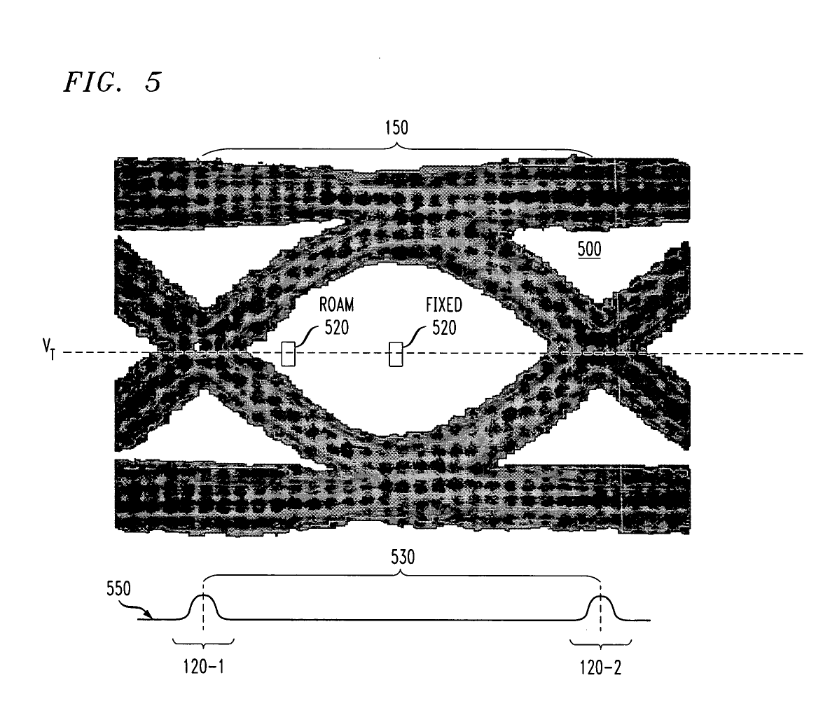

According to one aspect of the present invention, one or more latches, such as the latches 520-fixed and 520-roam of FIG. 5, are used to measure the data eye 110. The data eye measurements are evaluated to obtain an estimate of the duty cycle. In one exemplary implementation, the number of ones 130-1 and zeros 130-2 in each alternating unit interval 150 of a clock signal are measured by the one or more latches and compared as an estimate of the duty cycle. As shown in FIG. 1, the first data eye 110-1 exhibits x ones in the unit interval 150-1 and the second data eye 110-2 exhibits y zeros in the unit interval 150-2. A 50% duty cycle, for example, should exhibit x ones and y zeros for each alternating unit interval 150, where x and y are equal. If x and y are not equal, then duty cycle distortion is known to exist.

As discussed further below in conjunction with FIG. 5, two latches 520-fixed and 520-roam can be used to determine when the signal 100 is at a zero-crossing point, such as zero-crossing crossing points 120-1, 120-2. The time between two zero-crossing points corresponds to the unit interval 150 of the data eye. In the exemplary implementation shown in FIG. 1, the number of ones 130-1 or zeros 130-2 between two adjacent zero-crossing points 120-1, 120-2 in a clock signal can be counted and used as a measure of the duration of the unit interval (and thus, the duty cycle). The duty cycle of the signal 100 can thus be adjusted to maintain the size of each unit interval 150 within a desired tolerance.

In the exemplary embodiment shown in FIG. 1, the data eye monitor measures the signal 110 along the time axis to determine the number of ones 130-1 or zeros 130-2 between two adjacent zero crossing points 150-1, 150-2. It is determined if the number of ones 130-1 or zeros 130-2 satisfy a predefined duty cycle threshold. If the duty cycle threshold is not satisfied, the duty cycle is adjusted using a duty cycle correction circuit 700, discussed below in conjunction with FIG. 7.

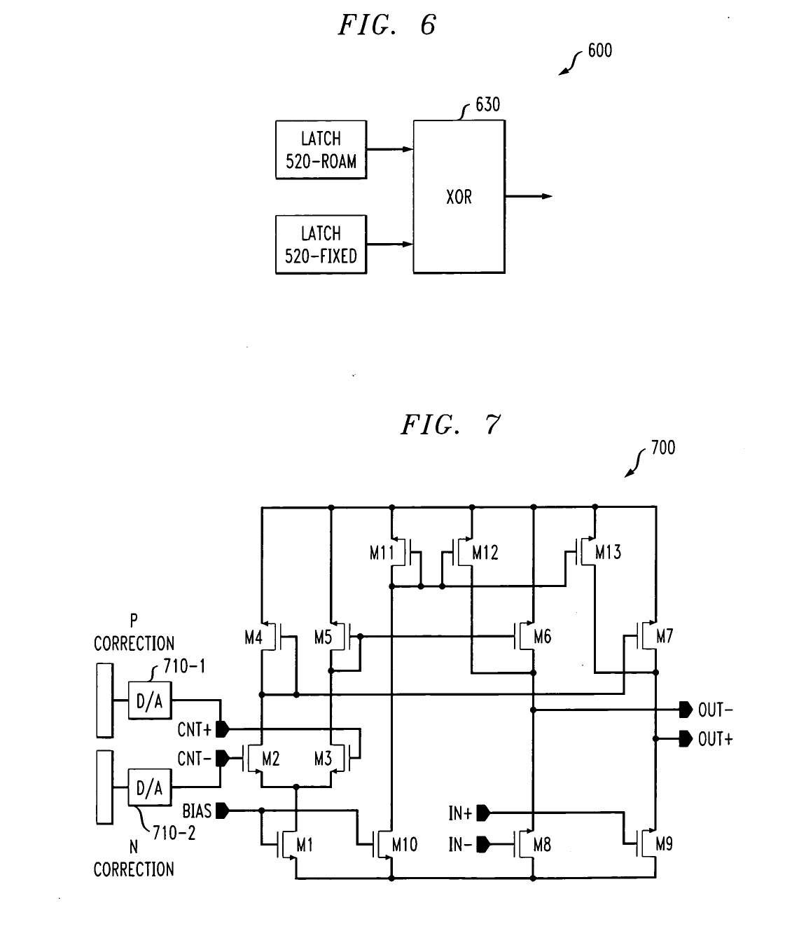

In a further variation, discussed further below in conjunction with FIGS. 5 and 6, the data eye monitor accumulates the measurements over time and generates a histogram 550. As discussed further below, the histogram 550 will contain peaks that correspond to points of zero crossing 120-1, 120-2 and 120-3 in the received signal. The peak-to-peak difference 530 between zero crossing points 120 in the histogram 550 can be used as an indication of the duty cycle of the signal.

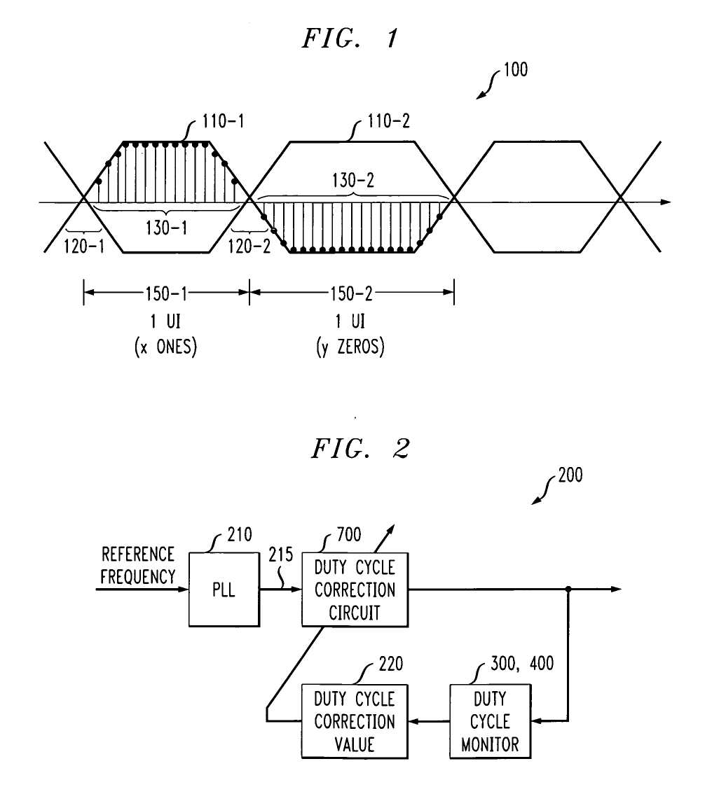

FIG. 2 illustrates an exemplary signal flow 200 for a duty cycle monitoring operation in accordance with the present invention. As shown in FIG. 2, a PLL 210 generates a signal in a known manner. As previously indicated, the duty cycle of the PLL 210 is the percentage of time that the output clock signal 215 has a given value. A PLL 210 should typically demonstrate a 50% duty cycle, such that the output clock signal should alternate between two amplitude values, each for 50% of the total duration. Duty cycle mismatches arise due to mismatches in the devices and due to variations of the differential signal paths for clock and data.

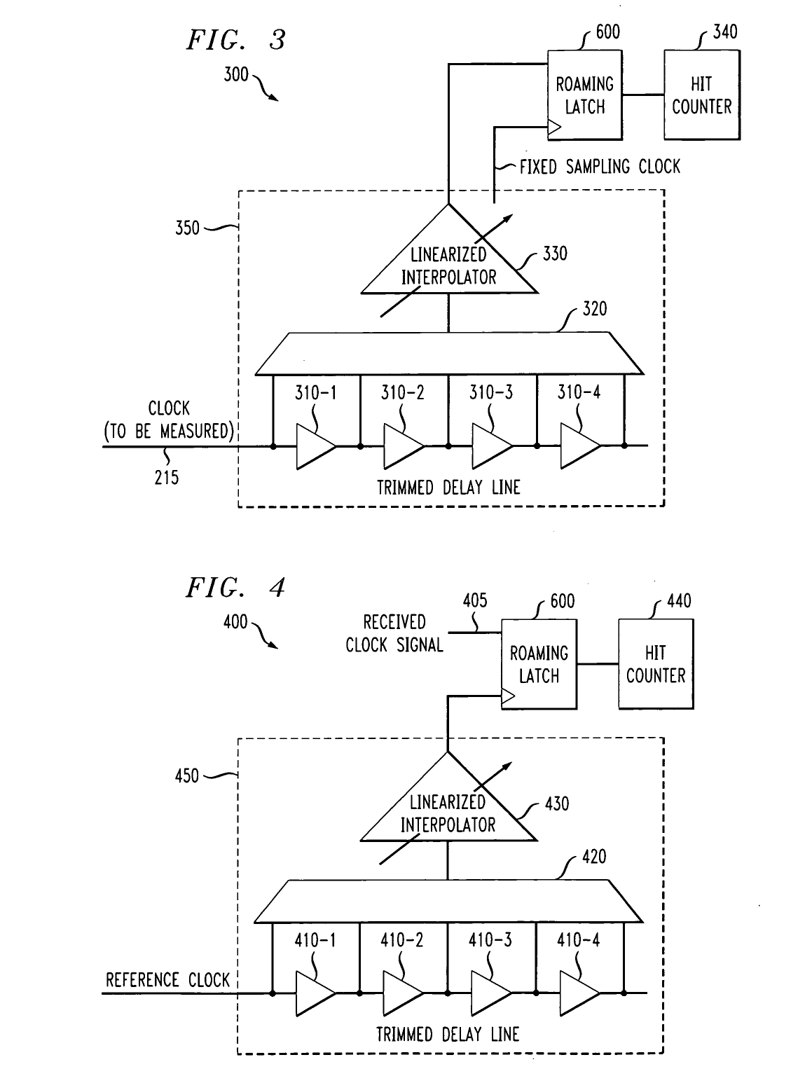

According to one aspect of the invention, a duty cycle correction circuit 700 is employed to ensure that the duty cycle of the PLL 210 satisfies a predefined duty cycle threshold. While the duty cycle correction circuit 700 may be implemented using any known digital duty cycle correction technique, an exemplary duty cycle correction circuit 700 is discussed below in conjunction with FIG. 7. The present invention employs a duty cycle monitor 300, 400, discussed below in conjunction with FIGS. 3 and 4, to measure the duty cycle of the clock signal 215. In one exemplary implementation, the duty cycle monitor 300, 400 generates an 8 bit digital value indicating a required duty cycle correction that is applied by stage 220 to the duty cycle correction circuit 700. The exemplary duty cycle correction circuit 700 will convert the digital value to an analog value.

FIG. 3 is a schematic block diagram of a first embodiment of a duty cycle monitor 300 incorporating features of the present invention. In the embodiment shown in FIG. 3, the duty cycle of a clock signal generated by the exemplary PLL 210 is corrected. As shown in FIG. 3, the output 215 of the PLL 210 (FIG. 2) is applied to an interpolation circuit 350 that will vary the phase of the clock signal 215 so that it can be sampled along the time axis. The interpolation circuit 350 comprises a trimmed delay line 310 having an exemplary four delay elements 310-1 through 310-4 in the exemplary embodiment. The output of each delay element 310-1 through 310-4 has a phase offset relative to one another, in a known manner. The delay elements in the delay line 310 produce multiple clock phases that can be interpolated so that any phase within the period of the clock signal 215 can be selected.

In the exemplary embodiment shown in FIG. 3, the delay line 310 can be tapped at the output of the four delay elements 310 to provide four corresponding interpolation regions. Each region is separately selected by a multiplexer 320 and separately interpolated by the interpolator 330, in a known manner. When the boundary of an interpolation region is reached, the interpolator 350 switches to the adjacent region. In the exemplary embodiment of FIG. 3, each region of interpolation spans a portion of the clock signal 215, and each delay element in the bank 310 provides a delay of 1/N of the period of the clock signal 215, where N determines the resolution of the duty cycle monitor. In one exemplary embodiment, there are two delay elements 310 per data eye 110.

The output of the interpolator 330 is applied to the data input of a roaming latch 600, discussed below in conjunction with FIG. 6. A fixed reference clock, having substantially the same period as the clock signal 215, is applied to the clock input of the latch 600. A hit counter 340 determines the number of ones 130-1 or zeros 130-2 between zero crossing points 120, in accordance with the embodiment of the invention shown in FIG. 1.

FIG. 4 is a schematic block diagram of a second embodiment of a duty cycle monitor 400 incorporating features of the present invention. In the embodiment shown in FIG. 4, the duty cycle of a received signal 405 is corrected. The received signal 405 may be a clock signal or may contain random data and is applied to the data input of a roaming latch 600.

A source of phase controlled data is applied to the clock input of the roaming latch 600, discussed below in conjunction with FIG. 6. The source of phase controlled data may be an interpolation circuit 450, such as those described in, for example, U.S. patent application Ser. No. 11/020,021, entitled, “Phase Interpolator Having a Phase Jump,” incorporated by reference herein. The interpolation circuit 450 operates in a similar manner to the interpolation circuit 350 discussed above. A reference clock, having substantially the same period as the received signal 405, is applied to the trimmed delay line 410. In this manner, the reference clock signal is shifted in time to control the sampling of the received signal 405 at various points in time. When the received signal is known to be a clock signal, the hit counter 440 determines the number of ones 130-1 or zeros 130-2 between zero crossing points 120, in accordance with the embodiment of the invention shown in FIG. 1. When the received signal 405 contains random data, the histogram 550 is evaluated to obtain the peak-to-peak difference 530 between zero crossing points 120 as an indication of the duty cycle of the signal.

FIG. 5 illustrates the measurement of the unit interval of a data eye 500 in accordance with one embodiment of the present invention. As shown in FIG. 5, and discussed further below in conjunction with FIG. 6, two latches 520-fixed and 520-roam can be used to measure the unit interval 150 of each data eye 110. Generally, the two latches 520-fixed and 520-roam are used to determine when the signal 100 is at a zero-crossing point, such as zero-crossing points 120-1, 120-2. The fixed latch 520-fixed is fixed at approximately the center of each unit interval. The roaming latch 520-roam samples the signal based on the roaming clock. The time between two zero-crossing points corresponds to the unit interval of the data eye. In addition, the number of “hits” 130-1, 130-2 between two adjacent zero-crossing points 120-1, 120-2, can be counted and used as a measure of the duration of the unit interval (and thus, the duty cycle). Generally, in one exemplary embodiment, a “hit” occurs whenever the two latches 520-fixed and 520-roam do not measure the same value. In this manner, a hit occurs when the roaming latch 520-roam is in a zero crossing point. It is noted that when the latches 520 have a threshold of 0 Volts (or based on the common mode of the incoming signal), a zero crossing is detected using the techniques of the present invention.

FIG. 5 also includes a histogram 550 that is used in one variation to identify the zero crossing points 120. Generally, in the exemplary embodiment shown in FIG. 5, peaks in the histogram 550 correspond to the zero crossing points 120. The histogram 550 is obtained using the output of the hit counter 340, 440. As discussed further below, the hit counter 340, 440 will generate a binary value of 0 when the outputs of the two latches 520-fixed and 520-roam match, and will generate a binary value of 1 when the outputs of the two latches 520-fixed and 520-roam do not match. Thus, binary values of 1 will be expected when the roaming latch 520-roam is sampling in the locations of zero-crossing points 120-1, 120-2. Similarly, binary values of 0 will be expected when the latch 520-roam is sampling in a location 130 that is inside the data eye 500. The peak-to-peak difference 530 between zero crossing points 120 in the histogram 550 can be used as an indication of the duty cycle of the signal.

FIG. 6 illustrates one embodiment of the roaming latches 600 of FIGS. 3 and 4. As shown in FIG. 6, the outputs of the two latches 520-fixed and 520-roam of FIG. 5 are applied to an exclusive OR (XOR) gate 630. The XOR gate 630 compares the value of the two latches 520-fixed and 520-roam. If the values of the two latches 520-fixed and 520-roam match, the XOR gate 630 will generate a binary value of 0 and if the values of the two latches 520-fixed and 520-roam do not match, the XOR gate 630 will generate a binary value of 1, in a known manner. Thus, a “hit” occurs when the values of the two latches 520-fixed and 520-roam do not match.

The relative value of the two latches 520-fixed and 520-roam provides an indication of location of the data transitions (zero crossings). If the two latches 520-fixed and 520-roam have the same value, they are said to match. Thus, for samples taken inside a data eye, it would be expected that the value of the two latches 520-fixed and 520-roam match one another. For samples taken along the boundary of the data eye (i.e., in the zero crossing), it would be expected that some of the values of the two latches 520-fixed and 520-roam will match one another. For samples taken outside a data eye, it would be expected that the values of the two latches 520-fixed and 520-roam will not match.

FIG. 7 is a circuit diagram illustrating an exemplary implementation of the duty cycle correction circuit 700. The exemplary duty cycle correction circuit 700 is based on a duty cycle correction circuit shown in Toru Ogawa and Kenji Taniguchi, “A 50% Duty-Cycle Correction Circuit for PLL Output,” Proc. of the 2002 Int'l Symp. on Circuits and Systems, Vol. 4, 21-24 (May 2002), incorporated by reference herein. Generally, the digital output of the duty cycle monitor 300, 400, is applied to the duty cycle correction circuit 700 which contains digital-to-analog converters 710 to generate corresponding analog values that are processed by the duty cycle correction circuit 700, in a known manner.

FIG. 8 is a schematic block diagram illustrating a control system 800 for performing duty cycle monitoring. In one exemplary implementation, the latches 520-fixed and 520-roam are stepped through each of the horizontal positions associated with a given eye, controlled by a timer 810. Once the zero crossing points 120 (FIG. 1) are identified, the unit interval of the data eye can be determined. In one exemplary implementation, for each sampled location, a counter 820 counts the number of mismatches during the predefined duration between the two latches 520-fixed and 520-roam. The count metric generated by the counter 820 is provided, for example, via a serial/parallel interface 830 to a computing device 840, such as a personal computer or an 8051 microprocessor, for further analysis. Generally, once the sampled data is loaded into the computing device 840, the data can be analyzed and the duty cycle correction can be obtained and adjusted, if necessary, by the duty cycle correction circuit 700.

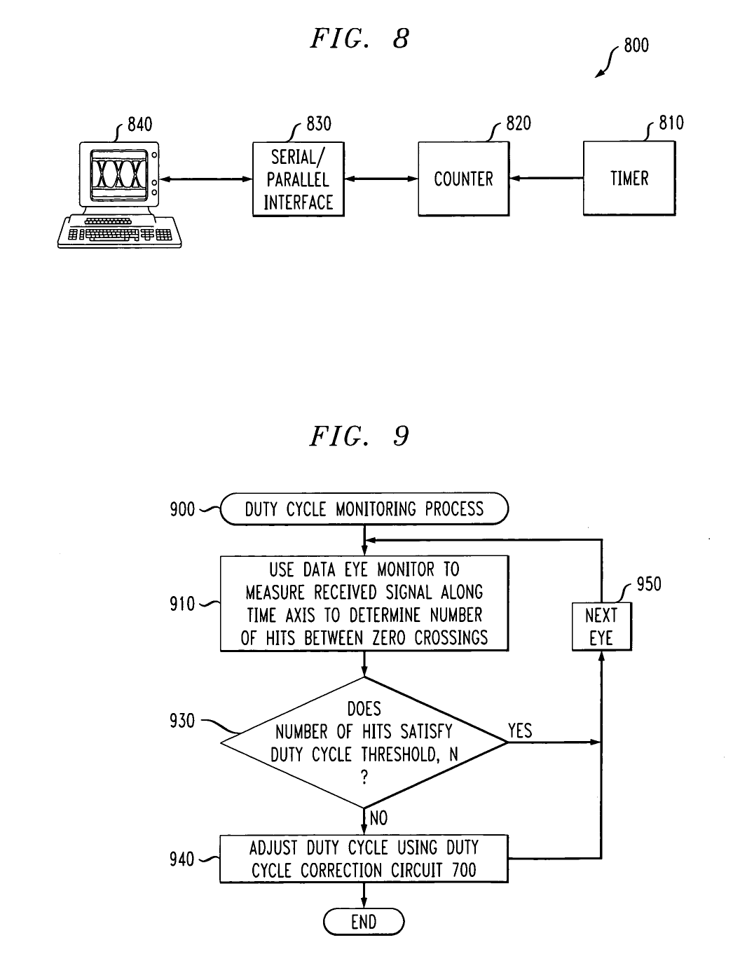

FIG. 9 is a flow chart describing an exemplary duty cycle monitoring process 900 incorporating features of the present invention. As shown in FIG. 9, the exemplary duty cycle monitoring process 900 initially measures the signal 110 along the time axis during step 910 to determine the number of hits (x ones and y zeros, as in FIG. 1) between two adjacent zero crossing points 150-1, 150-2. During step 930, it is determined if the determined number of hits satisfy a predefined duty cycle threshold. If the duty cycle threshold is satisfied, the duty cycle of the next data eye 110 can be evaluated during step 950. If the duty cycle threshold is not satisfied, the duty cycle is adjusted during step 940 using the duty cycle correction circuit 700 (FIG. 7). As indicated above in conjunction with FIG. 5, a further variation evaluates the peak-to-peak difference 530 of the zero crossings in the histogram 550 as an estimate of the duty cycle.

It is noted that the accuracy of the present invention can be improved if one or more techniques are employed to compensate for channel distortions. For example, one or more of pre-emphasis, zero equalization and decision-feedback equalization techniques can be employed to improve the quality of the received signal. For a discussion of techniques for evaluating the quality of the data eye, see, United States patent application, entitled “Method and Apparatus for Determining One or More Channel Compensation Parameters Based on Data Eye Monitoring,” (Attorney Docket No. Abel 17-58-22-63), filed contemporaneously herewith and incorporated by reference herein.

A plurality of identical die are typically formed in a repeated pattern on a surface of the wafer. Each die includes a device described herein, and may include other structures or circuits. The individual die are cut or diced from the wafer, then packaged as an integrated circuit. One skilled in the art would know how to dice wafers and package die to produce integrated circuits. Integrated circuits so manufactured are considered part of this invention.

While exemplary embodiments of the present invention have been described with respect to digital logic blocks, as would be apparent to one skilled in the art, various functions may be implemented in the digital domain as processing steps in a software program, in hardware by circuit elements or state machines, or in combination of both software and hardware. Such software may be employed in, for example, a digital signal processor, micro-controller, or general-purpose computer. Such hardware and software may be embodied within circuits implemented within an integrated circuit.

Thus, the functions of the present invention can be embodied in the form of methods and apparatuses for practicing those methods. One or more aspects of the present invention can be embodied in the form of program code, for example, whether stored in a storage medium, loaded into and/or executed by a machine, or transmitted over some transmission medium, wherein, when the program code is loaded into and executed by a machine, such as a computer, the machine becomes an apparatus for practicing the invention. When implemented on a general-purpose processor, the program code segments combine with the processor to provide a device that operates analogously to specific logic circuits.

It is to be understood that the embodiments and variations shown and described herein are merely illustrative of the principles of this invention and that various modifications may be implemented by those skilled in the art without departing from the scope and spirit of the invention.

We claim:

1. A method for measuring a duty cycle of a signal, comprising:
sampling said signal for a plurality of different phases;
evaluating said samples to identify when said signal crosses a predefined amplitude value; and
estimating said duty cycle based on said points of predefined amplitude crossing.

2. The method of claim 1, wherein said crossing of a predefined amplitude value is a zero crossing.

3. The method of claim 1, wherein said sampling step further comprises the step of sampling said signal using one or more latches.

4. The method of claim 3, wherein one of said latches is fixed approximately in a center of a data eye associated with said signal and a second one of said latches can be repositioned based on said phase to sample said signal along a time axis.

5. The method of claim 4, wherein said signal crosses said predefined amplitude value when said two latches do not sample the same value of said signal.

6. The method of claim 1, further comprising the steps of determining a phase associated with each of said points of predefined amplitude crossing and determining said duty cycle based on a difference between said phases.

7. The method of claim 1, further comprising the step of correcting said duty cycle to provide a desired duty cycle ratio.

8. The method of claim 1, wherein said signal is a local clock signal.

9. The method of claim 1, wherein said signal is a signal received over a communication channel.

10. The method of claim 1, wherein said step of estimating said duty cycle further comprises the step of determining a number of occurrences of a first amplitude value or a number of occurrences of a second amplitude value for each unit interval.

11. The method of claim 1, wherein said step of estimating said duty cycle further comprises the steps of generating a histogram based on said sample values and determining a statistical variation between approximate peaks in said histogram.

12. A system for measuring a duty cycle of a signal, comprising:
one or more latches configured to sample said signal for a plurality of different phases; and
a duty cycle monitoring circuit configured to:
evaluate said samples to identify when said signal crosses a predefined amplitude value; and
estimate said duty cycle based on said points of predefined amplitude crossing.

13. The system of claim 12, wherein said crossing of a predefined amplitude value is a zero crossing.

14. The system of claim 12, wherein one of said latches is fixed approximately in a center of a data eye associated with said signal and a second one of said latches can be repositioned based on said phase to sample said signal along a time axis.

15. The system of claim 12, wherein said duty cycle monitoring circuit is further configured to determine a number of occurrences of a first amplitude value or a number of occurrences of a second amplitude value for each unit interval.

16. The system of claim 12, wherein said duty cycle monitoring circuit is further configured to generate a histogram based on said sample values and determine a statistical variation between approximate peaks in said histogram.

17. An integrated circuit, comprising:
a circuit for measuring a duty cycle of a signal, comprising:
one or more latches configured to sample said signal for a plurality of different phases; and
a duty cycle monitoring circuit configured to:
evaluate said samples to identify when said signal crosses a predefined amplitude value; and
estimate said duty cycle based on a statistical variation between said points of predefined amplitude crossing

18. The integrated circuit of claim 17, wherein one of said latches is fixed approximately in a center of a data eye associated with said signal and a second one of said latches can be repositioned based on said phase to sample said signal along a time axis.

19. The integrated circuit of claim 17, wherein said duty cycle monitoring circuit is further configured to determine a number of occurrences of a first amplitude value or a number of occurrences of a second amplitude value for each unit interval.

20. The integrated circuit of claim 17, wherein said duty cycle monitoring circuit is further configured to generate a histogram based on said sample values and determine a statistical variation between approximate peaks in said histogram.
